(19) United States
(12) Patent Application Publication
(10) Pub. No.: US 2010/0052181 A1
(43) Pub. Date: Mar. 4, 2010

(54) USING A CAP LAYER IN METALLIZATION SYSTEMS OF SEMICONDUCTOR DEVICES AS A CMP AND ETCH STOP LAYER

(76) Inventors: Thomas Werner, Moritzburg (DE); Kai Frohberg, Niederau (DE); Frank Feustel, Dresden (DE)

Correspondence Address: WILLIAMS, MORGAN & AMERSON, 10333 RICHMOND, SUITE 1100, HOUSTON, TX, 77042, US

(21) Appl. No.: 12/483,571

(22) Filed: Jun. 12, 2009

(30) Foreign Application Priority Data
Aug. 29, 2008 (DE) 10 2008 044 988.1

(51) Int. Cl. H01L 23/522; H01L 21/768; H01L 23/528

(52) U.S. Cl. 257/773; 438/675; 257/E21.585; 257/E23.145; 257/E23.151

(57) ABSTRACT

During the manufacture of advanced metallization systems, a dielectric cap layer formed on a sensitive dielectric material may be partially maintained during a CMP process for removing excess metal, thereby avoiding the necessity for depositing a dedicated etch stop material, as may be required in conventional approaches when substantially completely consuming the dielectric cap material during the CMP process. Hence, reduced process complexity and/or enhanced flexibility may be accomplished in combination with increased integrity of the low-k dielectric material.

### BACKGROUND OF THE INVENTION

1. Field of the Invention

The present disclosure generally relates to the field of fabricating semiconductor devices, and, more particularly, to metallization systems including low-k dielectric materials.

2. Description of the Related Art

Today's global market forces manufacturers of mass products to offer high quality products at a low price. It is thus important to improve yield and process efficiency to minimize production costs. This holds especially true in the field of semiconductor fabrication, since, here, it is essential to combine cutting-edge technology with volume production techniques. One important aspect in realizing the above strategy is seen in continuously improving device quality with respect to performance and reliability, while also enhancing the diversity of functions of semiconductor devices. These advances are typically associated with a reduction of the dimensions of the individual circuit elements, such as transistors and the like. Due to the continuous shrinkage of critical feature sizes, at least in some stages of the overall manufacturing process, frequently, new materials may have to be introduced to adapt device characteristics to the reduced feature sizes. One prominent example in this respect is the fabrication of sophisticated metallization systems of semiconductor devices in which advanced metal materials, such as copper, copper alloys and the like, are used in combination with low-k dielectric materials, which are to be understood as dielectric materials having a dielectric constant of approximately 3.0 and significantly less, in which case these materials may also be referred to as ultra low-k dielectrics (ULK). By using highly conductive metals, such as copper, the reduced cross-sectional area of metal lines and vias may at least partially be compensated for by the increased conductivity of copper compared to, for instance, aluminum, which has been the metal of choice over the last decades, even for sophisticated integrated devices.

On the other hand, the introduction of copper into semiconductor manufacturing strategies may be associated with a plurality of problems, such as sensitivity of exposed copper surfaces with respect to reactive components, such as oxygen, fluorine and the like, the increased diffusion activity of copper in a plurality of materials typically used in semiconductor devices, such as silicon, silicon dioxide, a plurality of low-k dielectric materials and the like, copper's characteristic of generating substantially no volatile byproducts on the basis of typically used plasma enhanced etch processes, and the like. For these reasons, sophisticated inlaid or damascene process techniques have been developed in which typically the dielectric material may have to be patterned first in order to create trenches and via openings, which may then be coated by an appropriate barrier material, followed by the deposition of the copper material. Consequently, a plurality of highly complex processes, such as the deposition of sophisticated material stacks for forming the interlayer dielectric material including low-k dielectrics, patterning the dielectric material, providing appropriate barrier and seed materials, filling in the copper material, removing any excess material and the like, may be required for forming sophisticated metallization systems, wherein the mutual interactions of these processes may be difficult to assess, in particular, as material compositions and process strategies may frequently change in view of further enhancing overall performance of the semiconductor devices.

For example, the continuous shrinkage of the critical dimensions may also require reduced dimensions of metal lines and vias formed in the metallization system of sophisticated semiconductor devices which may lead to closely spaced metal lines, which in turn may result in increased RC (resistive capacitive) time constants. These parasitic RC time constants may result in significant signal propagation delay, thereby limiting overall performance of the semiconductor device, although highly scaled transistor elements may be used in the device level. For this reason, the parasitic RC time constants may be reduced by using highly conductive metals, such as copper, in combination with dielectric materials of very reduced permittivity, also referred to as ULK materials, as previously discussed. On the other hand, these materials may exhibit significant reduced mechanical and chemical stability, for instance when exposed to the various reactive etch atmospheres and mechanical stress, for instance during etch processes, resist removal, the removal of excess metal by chemical mechanical polishing (CMP) and the like.

Due to the reduced mechanical stability of low-k dielectric materials in general and ULK materials in particular, typically a dielectric cap layer may be formed on the low-k dielectric material, which enhances the overall characteristics of the dielectric layer stack during the patterning of the low-k dielectric material and in particular during the process of removing excess material after filling in a conductive metal, such as copper. However, the provision of a specific dielectric cap layer may contribute to overall process complexity, as will be described with reference to FIGS. 1a and 1b in more detail.

FIG. 1a schematically illustrates a cross-sectional view of a semiconductor device 100 in a manufacturing stage in which a metallization system 120 may be formed above a substrate 101. The substrate 101 may represent any appropriate carrier material for forming therein and thereabove respective device levels, such as semiconductor materials for forming therein circuit elements in the form of transistors, capacitors, resistors and the like. Furthermore, the substrate 101 may also comprise an appropriate contact structure for connecting the circuit elements, i.e., corresponding contact areas, such as drain and source areas, gate electrodes, capacitor electrodes and the like, with the metallization system 120. For convenience, any such contact structure is not shown in FIG. 1a. In the example illustrated in FIG. 1a, the metallization system 120 may comprise a first metallization layer 110 including an appropriate low-k dielectric material 111, in which a plurality of metal lines 112 may be embedded. The metal lines may typically comprise a conductive barrier material 112A, such as a tantalum layer, a tantalum nitride layer, or any combination thereof. Furthermore, a highly conductive metal 112B, in the form of copper, copper alloy and the like, may ensure enhanced electrical performance, as discussed above. Furthermore, an etch stop layer 113 may be formed on the dielectric material 111 and the metal lines 112 and may be comprised of any appropriate material so as to provide the desired etch stop capabilities, possibly in combination with other characteristics, such as the confinement of the metal regions 112B, forming an appropriate interface with the highly conductive metal 112B in order to achieve a specified electromigration behavior and the like. For example, a plurality of dielectric materials, such as silicon nitride, silicon carbide, nitrogen-containing silicon carbide and the like, are frequently used as appropriate materials for the etch stop layer 113. Due to the etch stop capabilities of the layer 113, the material contained therein may typically have an increased dielectric constant compared to the low-k dielectric 111, which is to be understood as a dielectric material having a relative permittivity of approximately 3.0 and less. For this purpose, a plurality of well-established low-k dielectric materials are available, such as materials including silicon, carbon, oxygen, hydrogen or a plurality of polymer materials.

The metallization system 120 may further comprise a second metallization layer 130 which, in the manufacturing stage shown in FIG. 1a, may comprise a low-k dielectric material 131, which may be similar to the material 111 or which may have a different material composition, depending on the overall mechanical and electrical performance requirements of the metallization system 120. Furthermore, a dielectric cap layer 135 is formed on the dielectric material 131 so as to enhance overall characteristics of the material 131 during the further processing, i.e., during the patterning of the material 131 and the subsequent formation of metal-containing regions. For example, the cap layer 135 may be provided in the form of a silicon dioxide material with a thickness of 20-100 nm.

The semiconductor device 100 as shown in FIG. 1a may be formed on the basis of the following conventional process techniques. First, any circuit elements and other device features may be formed in and above the substrate 101, thereby using well-established process techniques in accordance with design requirements of the semiconductor device 100. Next, an appropriate contact structure (not shown) may be formed, for instance by depositing an appropriate dielectric material, such as silicon dioxide and the like, and patterning the same to receive openings, which may be filled with a metal-containing material such as tungsten and the like. Thereafter, the metallization system 120 may be formed, for instance, by depositing the dielectric material 111 for the metallization layer 110. For this purpose, any appropriate deposition technique, such as spin-on techniques, thermally activated chemical vapor deposition (CVD), plasma enhanced CVD and the like, may be used. Next, an appropriate cap material may be provided when the dielectric material 111 represents a critical material with respect to mechanical stability and the like, as is explained above. For instance, a similar material layer as the layer 135 may be formed, for instance, by any appropriate deposition technique, such as plasma assisted CVD, to provide enhanced overall mechanical and chemical characteristics of the dielectric material 111. Subsequently, the dielectric material 111 may be patterned, for instance, by using the cap material as a hard mask, if desired, and performing well-established anisotropic etch processes to form corresponding openings for the metal lines 112. Subsequently, the conductive barrier material 112A may be deposited, for instance, by sputter deposition and the like, followed by the electrochemical deposition of the copper material of the regions 112B. As previously discussed, during the corresponding electrochemical deposition, a significant amount of excess material may have to be provided to ensure a reliable filling of the various openings for the metal lines 112. Next, the excess material may be removed by chemical mechanical polishing (CMP) in which the corresponding cap layer may provide enhanced mechanical stability. During the CMP process, the excess metal and the barrier material 112A may be removed, while also the corresponding cap layer may be consumed so as to finally obtain the electrically isolated metal regions 112 and a substantially exposed dielectric material 111. Thereafter, the etch stop layer 113 may be formed, for instance, by plasma enhanced CVD, wherein any appropriate material or material compositions may be deposited, as may be required for the further processing of the device 100. For example, the etch stop layer 113 may also act as a confinement layer for passivating an exposed top surface 112S of the copper material 112B. For example, silicon nitride, silicon carbide and nitrogen-containing silicon carbide are appropriate materials, which may efficiently suppress the migration of copper atoms into the dielectric material 111 and which may also efficiently suppress the incorporation of reactive components, such as fluorine, oxygen and the like, into the copper regions 112B, which may otherwise result in reduced mechanical and electrical performance of the metal lines 112. Next, the low-k dielectric material 131 of the metallization layer 130 may be deposited, for instance by spin-on techniques, CVD and the like, as is also explained with reference to the dielectric material 111. Thereafter, the cap layer 135 may be formed to provide the desired characteristics for the subsequent patterning of the low-k dielectric material 131, as is also previously explained with reference to the dielectric material 111.

FIG. 1b schematically illustrates the semiconductor device 100 in a further advanced manufacturing stage in which metal regions 132 in the form of metal lines 132L and vias 132V are formed in the dielectric material 131. For this purpose, similar process techniques may be used as previously described with reference to the metallization layer 110. That is, the cap layer 135 and the dielectric material 131 may be patterned by well-established process techniques and subsequently a conductive barrier material 132A in combination with highly conductive copper material may be filled into the corresponding openings with a subsequent removal of any excess material by a CMP process 102, thereby forming the metal lines 132L and the vias 132V. During the CMP process 102, the cap layer 135, which may initially provide enhanced mechanical stability, may increasingly be consumed and may finally be substantially completely removed as illustrated in FIG. 1b. Thereafter, a further etch stop layer may be provided to confine the exposed metal regions 132 and provide corresponding etch stop capabilities for patterning a further dielectric material to be formed above the metallization layer 130.

As discussed above, forming the metallization layers 110 and 130 may include a plurality of deposition processes, for instance for forming the etch stop layer 113 and the cap layer 135 in order to provide the desired etch stop capabilities and mechanical and chemical characteristics when patterning low-k dielectric materials of sophisticated metallization systems. Since typically a plurality of metallization layers may be required, the number of process steps required for each metallization layer may significantly contribute to the overall cycle time and thus production costs for sophisticated semiconductor devices.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to techniques and semiconductor devices in which metallization layers may be formed on the basis of sensitive dielectric materials by providing a dielectric cap layer for enhancing mechanical and chemical characteristics during the patterning of the dielectric material, while the number of process steps may be reduced and/or the degree of flexibility in selecting appropriate materials for the metallization layer under consideration may be enhanced. For this purpose, the corresponding cap layer may be used at least during a planarization process for removing any excess metal, wherein at least a portion thereof may be maintained so as to act as a material for passivating the sensitive dielectric material during the further processing. For instance, the remaining portion of the dielectric cap material may be used as an etch stop material to protect the underlying dielectric material during a further pattering sequence for forming metal lines and vias of a subsequent metallization layer. Consequently, the deposition of a dedicated etch stop material, as may be used in conventional approaches, may be avoided, thereby reducing the overall process complexity. In some illustrative aspects disclosed herein, the dielectric cap layer provides enhanced flexibility in passivating the surface area of the metal regions formed in the sensitive dielectric material, since the sensitive dielectric material may be reliably covered by the dielectric cap layer, while on the other hand the surface areas of the metal regions may be exposed due to the preceding CMP process. Thus, in some illustrative embodiments disclosed herein, a conductive cap layer may be formed on the exposed metal regions while reliably protecting the sensitive dielectric material without requiring an additional deposition step for forming an etch stop layer, as is the case in conventional approaches.

One illustrative method disclosed herein comprises forming a cap material on a first low-k dielectric material of a metallization layer of a semiconductor device. The method further comprises forming an opening in the cap material and the first low-k dielectric material and filling in a metal in the opening. Furthermore, a portion of the cap material and excess material of the metal are removed by performing a planarization process to form a metal region. The method further comprises forming a second low-k dielectric material on a residual layer comprised of a residual of the cap material and patterning the second low-k dielectric material by using the residual layer as an etch stop material.

A further illustrative method disclosed herein comprises forming an opening in a dielectric layer stack of a metallization layer of a semiconductor device, wherein the dielectric layer stack comprises a first dielectric material and a dielectric cap layer formed on the first dielectric material. The method further comprises filling the opening with a conductive material and removing excess material from above the first dielectric material to form a metal region by performing a planarization process while maintaining at least a portion of the dielectric cap material. Finally, the method comprises forming a conductive cap layer on a top surface of the metal region.

One illustrative semiconductor device disclosed herein comprises a metallization system formed above a substrate. The metallization system comprises a first metallization layer comprising a first low-k dielectric material, a first dielectric cap material formed on the first low-k dielectric material and a metal line formed in the first low-k dielectric material and in the first dielectric cap material, wherein the first dielectric cap material is laterally connected to the metal line so as to form a portion of a sidewall of the metal line. The metallization system further comprises a second metallization layer comprising a second low-k dielectric material that is formed above the first dielectric cap material and the metal line, wherein the second metallization layer comprises a via connecting to the metal line.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a conventional semiconductor device during various manufacturing stages in forming a metallization system on the basis of separate etch stop materials and dielectric cap materials of metallization layers including a low-k dielectric material;

FIGS. 2a-2g schematically illustrate cross-sectional views of a semiconductor device during various manufacturing stages in forming a metallization system by using a dielectric cap material in combination with a dielectric material, such as a low-k dielectric material, and maintaining a portion of the dielectric cap material for forming thereon a further dielectric material of a subsequent metallization layer, according to illustrative embodiments;

FIG. 2h schematically depicts a cross-sectional view of the semiconductor device according to still further illustrative embodiments in which a conductive cap material may be selectively formed on the basis of a remaining portion of a dielectric cap material, thereby providing enhanced passivation of exposed metal regions;

FIG. 2i schematically illustrates a cross-sectional view of the semiconductor device during a CMP process for removing excess metal while maintaining a portion of a dielectric cap layer, which may exhibit a specific internal compressive stress level to enhance overall mechanical integrity of the lower lying sensitive dielectric material, according to further illustrative embodiments;

FIG. 2j schematically illustrates a cross-sectional view of a semiconductor device according to still further illustrative embodiments in which a dielectric cap layer may be provided in the form of one or more sub-layers so as to appropriately adjust the overall characteristics during the further processing; and

FIG. 2k schematically illustrates a cross-sectional view of the semiconductor device at a manufacturing stage in which exposed surface portions of metal regions may be passivated on the basis of a remaining portion of a dielectric cap layer.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure relates to semiconductor devices and techniques for forming the same in which enhanced flexibility and/or reduced overall process complexity may be accomplished due to the fabrication of sophisticated metallization systems by using a dielectric cap material for enhancing mechanical and other characteristics of a sensitive dielectric material, in particular during a CMP process, wherein a portion of the dielectric cap material may not be removed during the CMP process and may be used during the further processing, for instance in the form of an etch stop material and the like. Consequently, enhanced overall integrity of the sensitive dielectric material, which may be provided in the form of a low-k dielectric material or even a ULK (ultra low-k) dielectric material having a dielectric constant of 2.7 or less, may be achieved, since the sensitive dielectric material may not be exposed during and after a corresponding planarization process which is performed to remove any excess material of a previously deposited metal-containing material. Moreover, the deposition of a further etch stop material, as is typically provided in conventional approaches, may be avoided, thereby contributing to enhanced overall process efficiency. In some illustrative embodiments, the maintained portion of the dielectric cap layer may be used as a protective material during an appropriate passivation of exposed surface areas of the metal regions formed in the sensitive dielectric material and the remaining portion of the cap layer. For example, a selective electrochemical deposition process may be performed, substantially without affecting the sensitive dielectric material, due to the presence of the dielectric cap material. In other cases, non-selective electrochemical deposition processes, or any other deposition processes, may be used, possibly in combination with a corresponding lithographical patterning step, in order to form a corresponding passivation layer on the exposed metal regions, while the remaining portion of the cap material may act as an efficient etch stop or protection material. Consequently, an increased degree of flexibility in appropriately “designing” the electromigration characteristics of a top surface of the metal regions may be achieved without degrading the characteristics of the sensitive dielectric material. In still other illustrative embodiments, the dielectric cap material may be provided as a compressively stressed material, thereby even further enhancing the overall mechanical integrity of the underlying dielectric material, in particular during the corresponding CMP process. In still other illustrative embodiments, the dielectric cap layer may be provided in the form of two or more sub-layers so as to appropriately adjust the overall characteristics with respect to the behavior during the CMP process, the etch process, the lithographical patterning and the like.

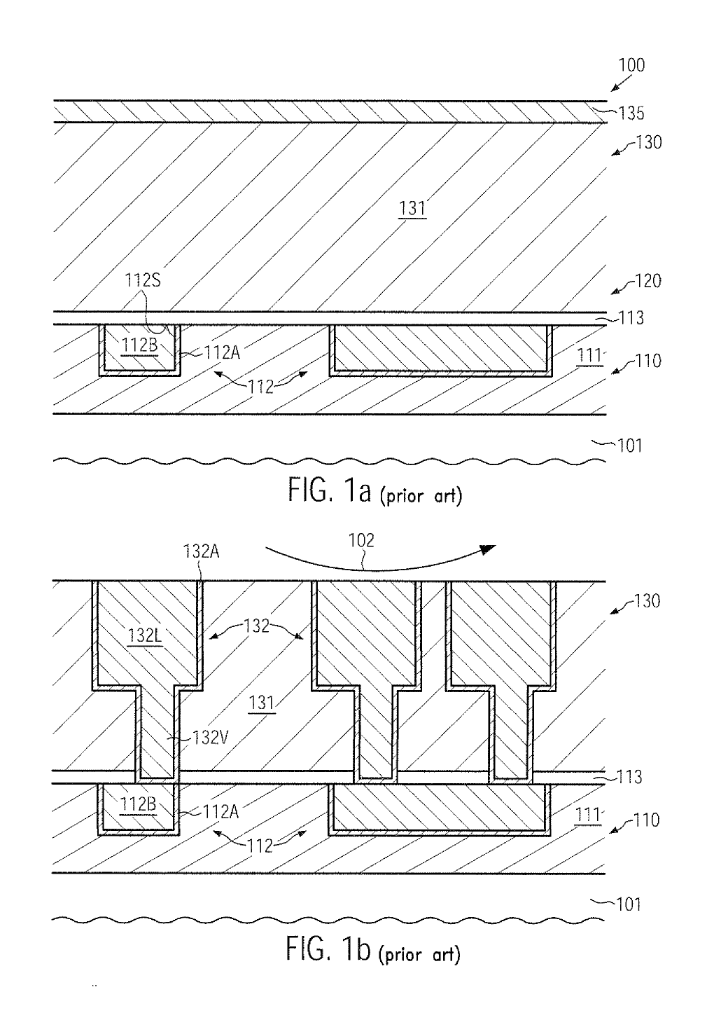

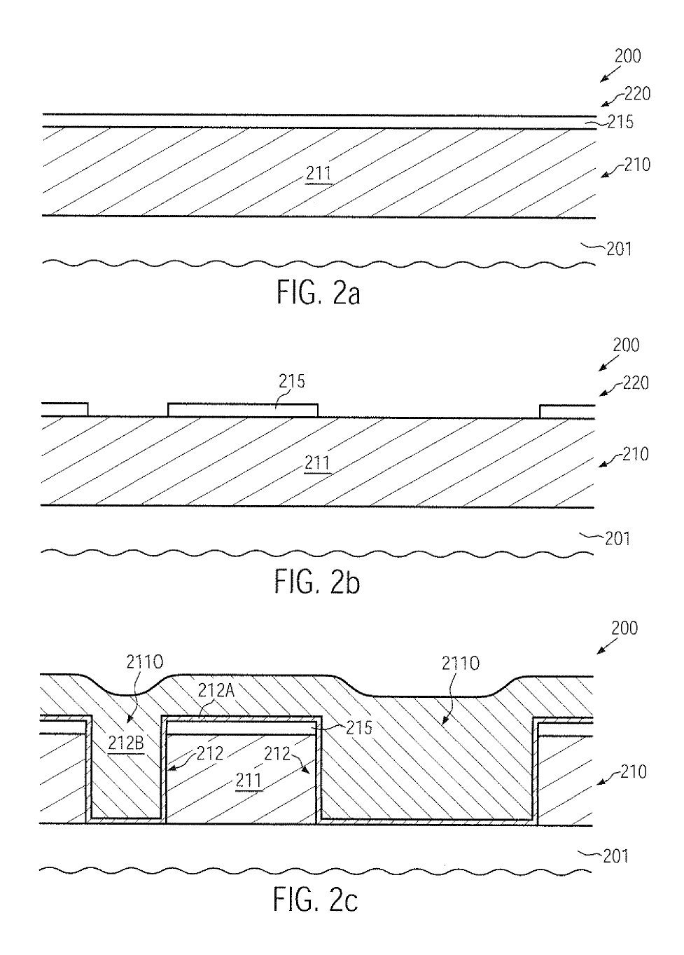

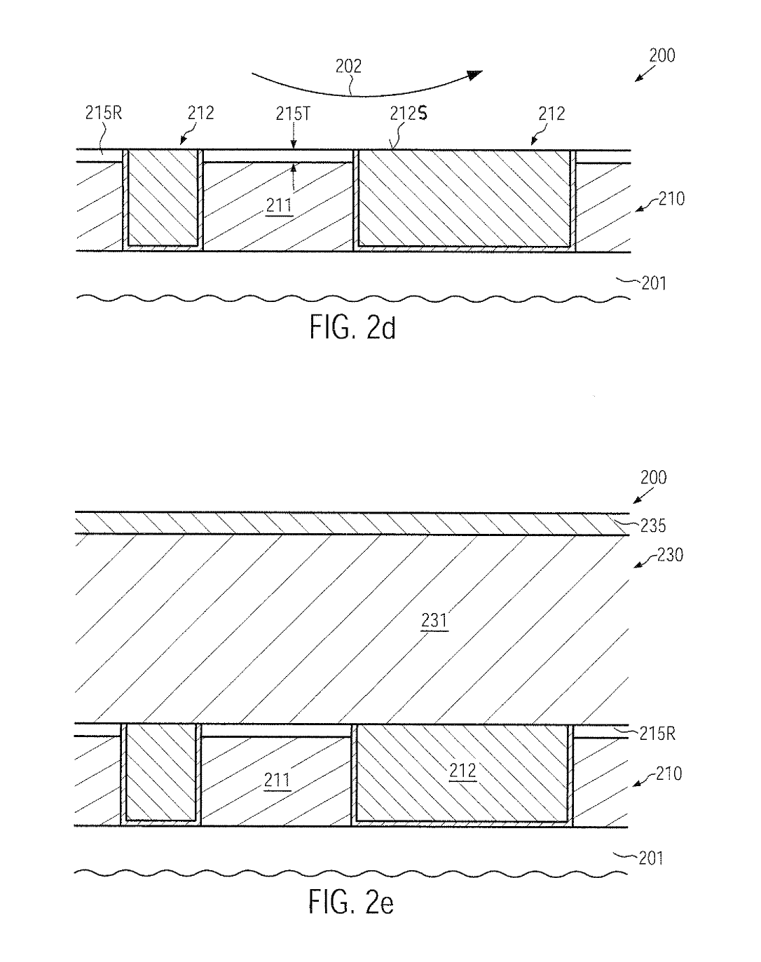

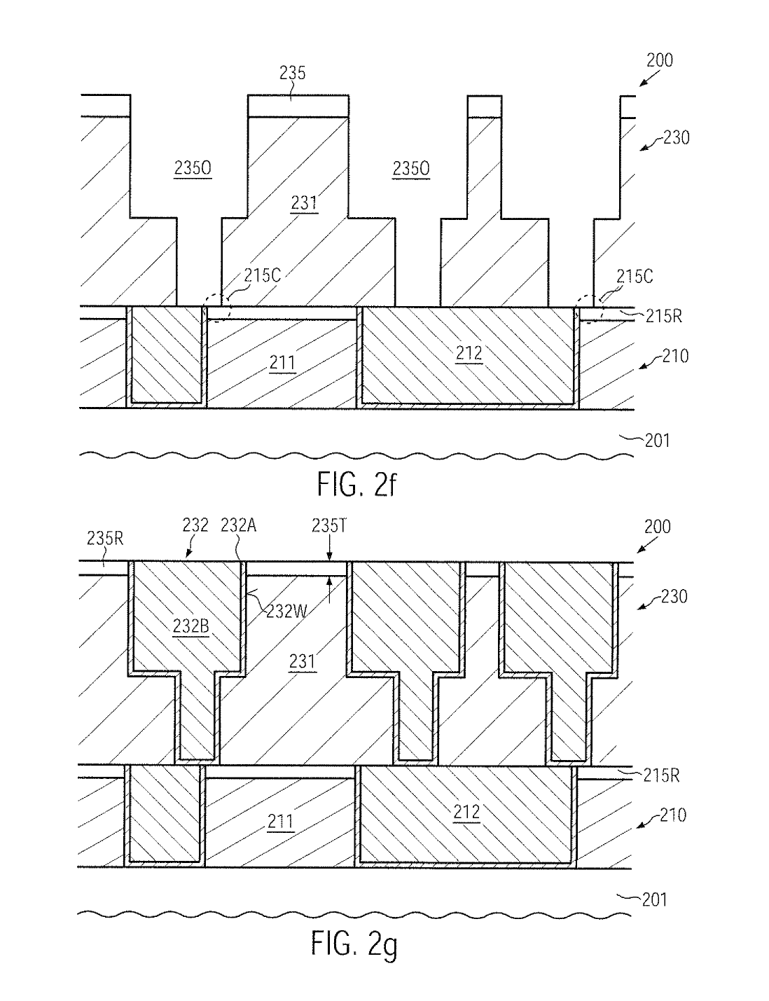

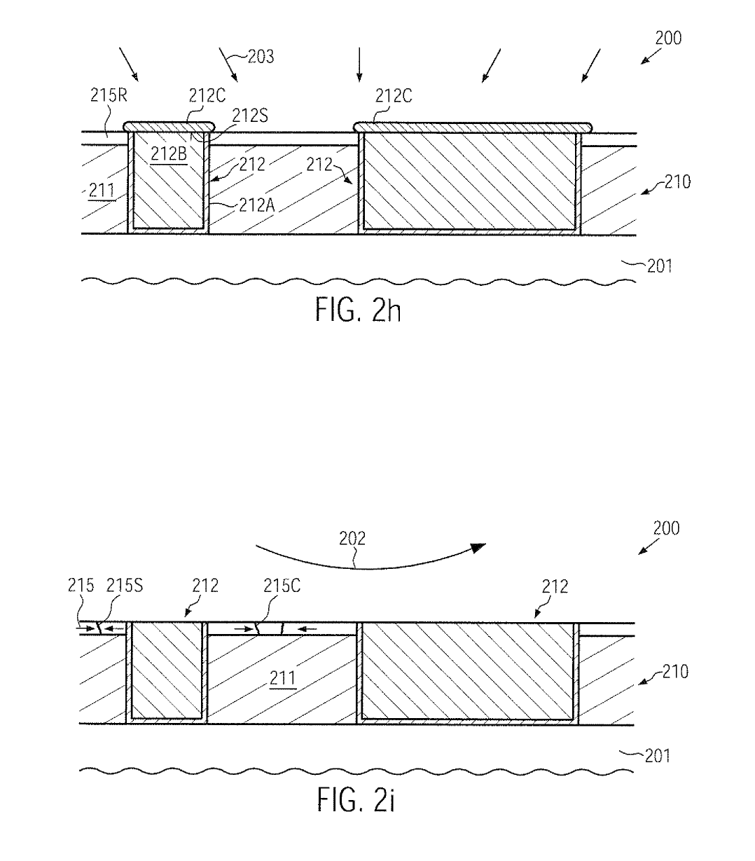

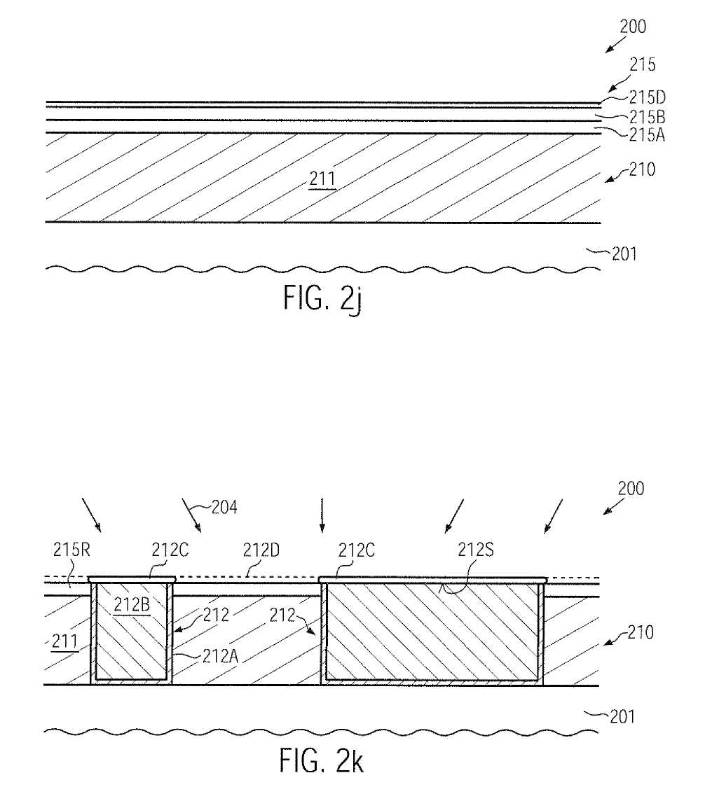

With reference to FIGS. 2a-2k, further illustrative embodiments will now be described in more detail, wherein reference may also be made to FIGS. 1a-1b if appropriate.

FIG. 2a schematically illustrates a cross-sectional view of a semiconductor device 200 in a manufacturing stage in which a metallization system 220 is to be formed above a substrate 201. It should be appreciated that the substrate 201 is to represent any appropriate carrier material for forming therein and thereabove circuit elements, contact elements and the like which may be required for obtaining the desired configuration and performance of the semiconductor device 200. For convenience, any such further device levels are not shown in FIG. 2a. The substrate 201 may comprise an appropriate carrier material in combination with one or more semiconductor layers in and above which circuit elements may be formed, such as transistors, capacitors, resistors and the like, as may also be described with reference to the semiconductor device 100. In sophisticated applications, critical dimensions of corresponding circuit elements, such as a gate length of field effect transistors, may be approximately 50 nm and less, thereby typically requiring advanced metallization layers in the metallization system 220, which may typically be accomplished by using sensitive dielectric materials, such as low-k dielectrics in combination with highly conductive metals, such as copper, copper alloys, silver and the like, as is also previously discussed. As is also previously described with reference to the semiconductor device 100, the substrate 201 may also include an appropriate contact structure for connecting corresponding circuit elements with the metallization system 220. In other cases, a corresponding contact structure may represent a portion of the metallization system 220. In the manufacturing stage shown, the metallization system 220 may comprise a first metallization layer 210 in an early manufacturing stage. That is, the metallization layer 210 may comprise a dielectric material, which may represent a low-k dielectric material having a reduced mechanical integrity, as is explained above. For instance, the dielectric constant of the material 211 may be approximately 3.0 and less, for instance 2.7 and less, if ULK materials are considered. For this purpose, a plurality of well-established low-k materials are available, which may have a more or less pronounced porous state, which may typically result in an even further reduced mechanical stability. Furthermore, a dielectric cap material 215 may be formed on the dielectric material 211 and may have any appropriate material composition so as to enhance the overall integrity of the material 211 during the further processing and which may also provide the desired behavior during a pattern process for forming a further metallization layer above the layer 210, as will be described later on in more detail. The dielectric cap layer 215 may thus be provided with any appropriate material composition and layer thickness such that at least a portion thereof may be maintained during a CMP process for removing any excess metal in a later manufacturing stage. For instance, the dielectric cap layer 215 may be comprised of silicon dioxide, silicon nitride, silicon carbide, nitrogen-containing silicon carbide, silicon oxynitride, or any combination with a thickness of approximately 10-100 nm, depending on the overall process requirements.

The semiconductor device 200 as shown in FIG. 2a may be formed on the basis of the following processes. After forming respective circuit elements and other features, such as contact elements and the like, in and above the substrate 201, as is also discussed with reference to the semiconductor device 100, the dielectric material 211 of the metallization layer 210 may be deposited. For this purpose, any appropriate deposition technique may be used, as is also discussed above. Next, the dielectric cap layer 215 may be formed by depositing one or more materials with the desired configuration and thickness as desired. For example, in some illustrative embodiments, the dielectric cap layer 215 may also be used as a hard mask for the subsequent patterning of the dielectric material 211. In this case, the layer 215 may be formed such that at least a surface portion thereof may provide the desired etch stop capabilities during a subsequent anisotropic etch process for patterning the dielectric material 211. In other cases, the layer 215, or at least an upper portion thereof, may act as an antireflective coating (ARC) material during a lithography process so that the corresponding optical characteristics, such as index of refraction, extinction coefficient and the like, may be appropriately selected by using any appropriate material composition. For instance, the optical characteristics of silicon dioxide may be appropriately adjusted by varying a degree of nitrogen incorporated therein to form a silicon oxynitride material having the desired optical response with respect to a corresponding exposure wavelength used for lithographically forming a resist mask. In other cases, respective optical relevant interfaces may be defined in the dielectric cap layer 215 by providing different material compositions to adjust reflection and absorption characteristics of the layer 215. For this purpose, well-established plasma assisted deposition techniques are available and may be used.

FIG. 2b schematically illustrates the semiconductor device 200 in a further advanced manufacturing stage in which the dielectric cap layer 215 may be patterned so as to provide an etch mask for the subsequent etching of the dielectric material 211. For this purpose, a resist material may be patterned by lithography in accordance with well-established process techniques. Thereafter, the layer 215 may be patterned on the basis of the corresponding resist mask, which may be removed prior to actually reaching the dielectric material 211. In other illustrative embodiments, the layer 215 and the dielectric material 211 may be etched in a common etch process on the basis of a corresponding etch mask (not shown). Thereafter, the dielectric material 211 may be etched on the basis of well-established anisotropic etch techniques so as to form corresponding openings, such as trenches and the like, as may be required for corresponding metal regions in the metallization layer 210. It should be appreciated that an appropriate material may be provided above the substrate 201 so as to appropriately control the corresponding etch process.

FIG. 2c schematically illustrates the semiconductor device 200 in a further advanced manufacturing stage. That is, metal regions 212, for instance in the form of metal lines, may be formed in the dielectric material 211 and the dielectric cap material 215, wherein the metal regions 212 may comprise a conductive barrier layer 212A and a highly conductive metal 212B, such as copper, copper alloys, silver, aluminum and the like, depending on the overall requirements with respect to conductivity and electromigration performance. In the manufacturing stage shown, the highly conductive metal 212B may be provided with a certain amount of excess thickness so as to reliably fill the corresponding openings 211O in the dielectric material 211. As previously explained, the openings 211O may be formed on the basis of an appropriate etch mask, such as the patterned dielectric cap layer 215 (see FIG. 2b) or any other appropriate etch mask. Thereafter, the conductive barrier material 212A may be formed, for instance, by sputter deposition, electrochemical deposition, chemical vapor deposition (CVD), self-limiting CVD techniques and the like, depending on the overall configuration of the semiconductor device 200. For instance, tantalum and tantalum nitride may frequently be used as barrier materials for copper-based metals. Thereafter, the highly conductive metal 212B may be filled in by, for instance, electrochemical deposition techniques, such as electroplating, electroless plating and the like. Thereafter, the excess material of the highly conductive metal 212B and of the barrier material 212A may be removed by a planarization process, which may typically comprise a CMP process.

FIG. 2d schematically illustrates the semiconductor device 200 at a final phase of a corresponding CMP process 202. As illustrated, any excess material of the highly conductive metal 212B may be removed and also the barrier layer 212A may be removed from horizontal device portions, thereby providing the metal regions 212 as electrically isolated metal regions. Furthermore, during the CMP process 202, material of the layer 215 may be removed, wherein, however, due to the initially selected layer thickness and/or material composition, a portion of the layer 215 may be maintained, thereby forming a residual layer 215R having an appropriate thickness 215T, which may be appropriate for the further processing of the device 200, for instance for acting as an etch stop or protection layer of the material 211 during the formation of a further metallization level. For instance, the layer thickness 215T may be in the range of approximately 10-50 nm, depending on the material composition of the initial layer 215 and the initial layer thickness. Consequently, the sensitive dielectric material 211 may not be removed during the CMP process 202 and may also maintain reliable coverage during the subsequent processing of the device 200. It should be appreciated that exposure to any reactive ambients, such as wet chemical cleaning processes and the like, may result in severe damage of sensitive dielectric materials, such as ULK materials, which may even require removal of a damaged surface zone of these materials in sophisticated applications. Consequently, by maintaining the residual layer 215R, enhanced overall integrity of the sensitive dielectric material 211 may be accomplished. It should be appreciated that, in some illustrative embodiments, exposed surface portions 212S of the metal regions 212 may be passivated prior to performing further manufacturing steps, as may also be explained in more detail later on.

FIG. 2e schematically illustrates the semiconductor device 200 in a further advanced manufacturing stage, in which the dielectric material 231 and a corresponding cap material 235 of a further metallization layer 230 may be provided. To this end, the dielectric material 231 may be deposited in the form of a low-k dielectric material on the residual layer 215R and on the metal regions 212, which may have formed thereon an appropriate passivation layer or cap layer (not shown) if a direct contact of the dielectric material 231 may be considered inappropriate. It should be appreciated that the dielectric material 231 may include two or more different material compositions, depending on the overall characteristics of the material 231. For example, one or more transition layers may be provided within the layer 231 to enhance overall adhesion of a ULK material to the residual layer 215R and the metal regions 212. In other cases, a low-k dielectric material may be directly deposited on the layer 215R. Next, the dielectric cap layer 235 may be formed, for instance on the basis of similar material compositions and techniques as is also described with reference to the cap layer 215 (FIGS. 2a-2b). It should be appreciated that the dielectric cap layer 235 may be provided with an appropriate initial layer thickness and material composition to enhance overall integrity of the material 231, while nevertheless enabling preserving a portion of the material 235 for the further processing, i.e., for the formation of a further metallization level.

FIG. 2f schematically illustrates the semiconductor device 200 in a further advanced manufacturing stage in which a plurality of openings 235O are formed in the dielectric material 231 and the dielectric cap layer 235. The openings 235O may be provided in any appropriate form, wherein at least a portion of the openings 235O may extend to one or more of the metal regions 212. For example, the openings 235O may represent trenches and via openings of the metallization layer 230. The openings 235O may be formed on the basis of any appropriate patterning regime, such as dual damascene techniques and the like, wherein the cap layer 235 may be patterned so as to act as a hard mask layer, as previously explained, while, in other cases, the materials 235 and 231 may be patterned in a common etch process. During a corresponding anisotropic etch process, which may be performed on the basis of well-established etch chemistries, the residual layer 215R may act as an etch stop material in device regions in which the openings 235O, or portions thereof, may not extend to underlying metal regions 212. For instance, critical areas 215C may be created by certain imperfections of the alignment procedure when lithographically defining the openings 235O. Moreover, during the anisotropic etch processes, a certain degree of reduced etch fidelity may result in a “misalignment” of the openings 235O with respect to the metal regions 212. In this case, the residual layer 215R may reliably stop the corresponding etch process, thereby maintaining integrity of the underlying material 211. On the other hand, the etch process may be stopped on or in the metal regions 212, which may comprise respective passivation materials or conductive cap layers, if required, as will also be described later on in more detail. Thus, the dielectric material 231 and the cap layer 235 may reliably be patterned on the basis of the residual layer 215R. Thereafter, the further processing may be continued, for instance, by depositing a conductive barrier material and filling in a conductive metal, such as copper and the like. Next, any excess material may be removed, as is also previously explained with reference to FIG. 2d when referring to the CMP process 202.

FIG. 2g schematically illustrates the semiconductor device 200 after the above-described process sequence. That is, the metallization layer 230 may comprise metal regions 232 including a conductive barrier material 232A and a highly conductive metal 232B. Furthermore, a remaining portion of the dielectric cap layer 235, now indicated as 235R, may be formed so as to cover the dielectric material 231. In a similar manner to the residual layer 215R, the residual layer 235R may laterally connect to the corresponding metal regions 232, thereby forming a portion of the sidewalls 232W thereof. The corresponding height of the respective portion of the sidewall 232W defined by the layer 235R is determined by a thickness 235T of the residual layer 235R. As previously explained, the thickness 235T, in combination with the corresponding material composition of the layer 235R, may be selected such that enhanced integrity during the further processing may be obtained, for instance, by forming a further dielectric material on the residual layer 235R and the metal regions 232, as is also described with reference to the layer 215R. Consequently, undue exposure of the sensitive dielectric material 231 after the deposition of the layer 235 may be avoided while also not requiring the deposition of a further etch stop material, as may typically be used in conventional approaches substantially completely consuming the corresponding cap material.

FIG. 2h schematically illustrates the semiconductor device 200 according to further illustrative embodiments in which a conductive cap layer 212C may be formed on the exposed surface portions 212S of the conductive material 212B. To this end, in one illustrative embodiment, a selective electrochemical deposition process 203 may be performed to deposit an appropriate cap material, such as an alloy including cobalt, tungsten, phosphorous, an alloy including cobalt, tungsten, boron, an alloy including nickel, molybdenum, boron and the like. During the electrochemical deposition process 203, the exposed surface portion 212S may act as a catalyzing material, thereby initiating the deposition of the corresponding metal species, while substantially avoiding a significant deposition on the residual layer 215R. Consequently, during the process 203, undue contact of the dielectric material 211 with the deposition ambient of the process 203 may be reliably avoided. Furthermore, prior to the deposition process 203, any appropriate cleaning processes, such as wet chemical cleaning techniques based on hydrofluoric acid, APM (ammonium hydrogen peroxide mixture) may be performed substantially without negatively affecting the dielectric material 211. Consequently, by means of the conductive cap layer 212C, the electromigration behavior and the confinement of the metal 212B may be adjusted at the top surface 212S, while also providing enhanced integrity of the conductive metal 212B during the further processing, for instance during the deposition of a dielectric material, such as the material 231 (see FIG. 2e). Moreover, the conductive cap layer 212C may act as an etch stop material during the patterning of the corresponding dielectric material when forming respective openings therein, such as the openings 235O (see FIG. 2f).

FIG. 2i schematically illustrates the semiconductor device 200 during a final phase of the CMP process 202 when removing excess material of the metallization layer 210, as is also previously discussed with reference to FIG. 2d. During the CMP process 202, typically, corresponding micro cracks 215C may be created, which may propagate into the dielectric material 211, thereby unduly reducing the overall mechanical stability thereof. In some illustrative embodiments, the dielectric cap layer 215 may be provided with a moderately high internal compressive stress level, as indicated by 215S, which may result in an appropriate “counter force” to suppress a widening and increasing of the micro cracks 215C, thereby also suppressing or at least reducing a propagation into the sensitive dielectric material 211. For instance, the dielectric cap layer 215 may be formed with an internal stress level of approximately 200 MPa to several hundred MPa or even higher, depending on the overall process and device requirements. For example, silicon dioxide, silicon nitride, nitrogen-containing silicon carbide and the like may be efficiently deposited on the basis of plasma enhanced CVD techniques with a high internal stress level by appropriately selecting process parameters, such as ion bombardment during the deposition, gas flow rates, temperatures, pressure and the like. Corresponding process recipes are well established in the art for forming compressively stressed dielectric materials and may be used for forming the layer 215. After the CMP process 202, a desired thickness of the layer 215 may be maintained, as is also discussed above.

FIG. 2j schematically illustrates the semiconductor device 200 according to further illustrative embodiments in which the dielectric cap layer 215 may be provided in the form of two or more sub-layers 215B, 215B and 215D in order to appropriately adjust the overall characteristics, for instance with respect to the CMP behavior, the etch stop capabilities, the ARC characteristics and the like. In the embodiment shown, the first sub-layer 215a may be deposited on the sensitive dielectric material 211 so as to provide the desired integrity of the material 211, when the sub-layer 215A may substantially represent the remaining portion of the layer 215. Thereafter, one or more further sub-layers, such as the layers 215B, 215D, may be formed. For example, the layer 215B may be deposited, for instance, during an in situ deposition process, by appropriately adjusting the process parameters such as the gas flow rates of precursor materials and the like. Thereafter, the layer 215D may be formed, for instance, by deposition, surface treatment and the like, according to the desired overall material characteristics. For example, the layers 215A, 215B may be provided with a different material composition to enable enhanced control of a corresponding CMP process, which may result in enhanced process uniformity in maintaining a desired remaining layer of the initial material 215. For instance, the sub-layer 215A may be provided in the form of a silicon dioxide material, while the layer 215B may be provided as a silicon oxynitride material, a silicon nitride material, a silicon carbide material and the like. If, for instance, a direct contact of the layer 215B with a subsequently deposited resist material may have to be suppressed, the layer 215D may be provided, for instance, in the form of a silicon dioxide material, or any other type of material, which may enable a direct contact with sensitive resist material. For example, if a contact of nitrogen with resist material or with a subsequent dielectric material is to be avoided, a corresponding nitrogen-containing material may be used for the layer 215B, which may be enclosed by the layers 215A, 215D, thereby suppressing undue exposure of sensitive material to a nitrogen species. It should be appreciated, however, that the material composition of the layer 215 may be selected in accordance with any other appropriate criteria, depending on the overall process and device requirements. After forming the layer 215, an appropriate patterning process may be performed to define respective openings in the layers 215 and 211, as is also previously explained. During the lithography process, if desired, a direct contact of resist material with nitrogen may be suppressed, even if one of the sub-layers of the layer 215 may include a nitrogen species. Thereafter, the further processing may be continued as previously described and finally a CMP process, such as the process 202 (see FIGS. 2d and 2i), may be performed, thereby removing the layers 215D, 215B, wherein the difference in material composition of the layers 215B and 215A may provide enhanced overall process control, thereby enabling a reliable adjustment of the remaining thickness within a specified value range. Thereafter, the further processing may be continued, as is also described above, wherein enhanced overall process uniformity may be accomplished. For example, a low-k dielectric material may be deposited, wherein also a direct contact to a nitrogen species may be avoided if the remaining portion of the layer 215 is substantially free of a nitrogen species.

FIG. 2k schematically illustrates the semiconductor device 200 according to further illustrative embodiments in which the residual layer 215R may be efficiently used as an etch stop or protection layer for forming a passivation layer or cap layer 212C, at least on the exposed surface portions 212S. For example, a non-selective process 204 may be performed to provide the cap layer 212C, for instance by depositing an appropriate material, wherein, in some cases, material 212D may also be deposited on the residual layer 215R. For this purpose, any appropriate physical or chemical vapor deposition techniques, electroplating processes and the like may be used. Thereafter, the undesired portion 212D may, at least partially, be removed by providing an appropriate mask (not shown) so as to cover at least the metal regions 212 while exposing the portions 212D. For this purpose, the same lithography mask may be used as is also employed for defining metal regions 212 within the dielectric material 211, however, on the basis of a negative resist, wherein the corresponding alignment accuracy may be less critical as long as a conductive path between neighboring metal regions 212 may be disconnected by a subsequent etch process for removing exposed portions of the material 212D. During the corresponding etch process, the residual layer 215R may act as a reliable etch stop material, thereby maintaining integrity of the dielectric material 211.

In other illustrative embodiments, the process 204 may include a surface treatment for forming the cap layer 212C, for instance in the form of a passivation layer and the like, while integrity of the material 211 may be maintained by the residual layer 215R. For example, a thin passivation layer may be formed on exposed copper surface areas by means of appropriate wet chemical etch chemistries, which may include corrosion inhibitors and the like, which may result in a thin substantially self-limiting passivation layer, which may protect the metal regions 212 during the further processing, for instance during the deposition of a further dielectric material.

As a result, the present disclosure provides techniques and semiconductor devices in which a dielectric cap layer may be maintained partially during a planarization process for removing excess material of metal and barrier material, thereby forming a portion of an upper sidewall area of the corresponding metal regions. The remaining dielectric cap layer may further ensure integrity of the sensitive dielectric material during the further processing, for instance during the deposition of a further low-k dielectric material for a subsequent metallization layer, thereby reducing overall process complexity, since a dedicated etch stop material may not be required, as is the case in conventional approaches. Furthermore, when selectively forming a conductive cap layer, the residual dielectric cap layer may provide integrity of the underlying dielectric material, thereby providing enhanced overall process flexibility.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a cap material on a first low-k dielectric material of a metallization layer of a semiconductor device;
forming an opening in said cap material and said first low-k dielectric material;
filling said opening with a metal;
removing a portion of said cap material and excess material of said metal by performing a planarization process to form a metal region;
forming a second low-k dielectric material on a residual layer comprised of a residual of said cap material; and
patterning said second low-k dielectric material by using said residual layer of said cap material as an etch stop material.

2. The method of claim 1, further comprising selectively forming a conductive cap layer on a top surface of said metal region prior to forming said second low-k dielectric material.

3. The method of claim 2, wherein selectively forming said conductive cap layer on a top surface of said metal region comprises performing an electrochemical deposition process.

4. The method of claim 1, wherein said cap material is formed with an internal compressive stress level.

5. The method of claim 4, wherein said cap material is formed with an internal compressive stress level of approximately 200 Mega Pascal or higher.

6. The method of claim 1, wherein forming said cap layer comprises depositing a silicon dioxide material.

7. The method of claim 1, wherein forming said cap layer comprises depositing a silicon and nitrogen containing material.

8. The method of claim 7, wherein said silicon and nitrogen containing material additionally comprises carbon.

9. The method of claim 1, wherein forming said cap layer comprises depositing a first sub-layer and a second sub-layer and wherein said first and second sub-layers differ in material composition.

10. The method of claim 1, wherein forming said opening in said first low-k dielectric material comprises patterning said cap material and using said cap material as a hard mask when forming said opening in the first low-k dielectric material.

11. The method of claim 1, further comprising forming a further cap material on said second low-k dielectric material, patterning said further cap material to form a second opening in said further cap material and said second low-k dielectric material, filling said second opening with a metal-containing material and removing material of said further cap material and said metal-containing material so as to form a further residual layer and a second metal region.

12. A method, comprising:
forming an opening in a dielectric layer stack of a metallization layer of a semiconductor device, said dielectric layer stack comprising a first dielectric material and a dielectric cap layer formed on said first dielectric material;
filling said opening with a conductive material;
removing excess material from above said first dielectric material to form an electrically conductive region by performing a planarization process while maintaining at least a portion of said dielectric cap material; and
forming a conductive cap layer on a top surface of said electrically conductive region.

13. The method of claim 12, wherein said conductive cap layer is formed by performing a selective electrochemical deposition process.

14. The method of claim 12, further comprising forming a second dielectric material above said maintained portion of said dielectric cap material.

15. The method of claim 14, further comprising patterning said second dielectric material by using said conductive cap layer and said maintained portion of said dielectric cap material as an etch stop material.

16. The method of claim 15, further comprising forming a second dielectric cap material on said second dielectric material prior to patterning said second dielectric material.

17. The method of claim 16, wherein patterning said second dielectric material comprises forming a mask from said second dielectric cap material and using said mask as an etch mask for etching said second dielectric material.

18. The method of claim 12, wherein said dielectric cap material is formed with an internal compressive stress level.

19. A semiconductor device, comprising:
a metallization system formed above a substrate, said metallization system comprising:
a first metallization layer comprising a first low-k dielectric material, a first dielectric cap material formed on said first low-k dielectric material and a metal line formed in said first low-k dielectric material and said first dielectric cap material, said first dielectric cap material laterally connecting to said metal line so as to form a portion of a sidewall of said metal line, and
a second metallization layer comprising a second low-k dielectric material formed above said first dielectric cap material and said metal line, said second metallization layer comprising a via connecting to said metal line.

20. The semiconductor device of claim 19, further comprising a conductive cap layer formed on a top surface of said metal line.

21. The semiconductor device of claim 20, wherein said first dielectric cap material has an internal compressive stress level.

22. The semiconductor device of claim 19, further comprising a second dielectric cap material formed on said second low-k dielectric material, wherein said second dielectric cap material forms a portion of a sidewall of a second metal line formed in said second low-k dielectric material and said second dielectric cap material.

23. The semiconductor device of claim 19, wherein a dielectric constant of said first low-k dielectric material is less than a dielectric constant of said first dielectric cap material.
